(19) United States
(12) Patent Application Publication
(10) Pub. No.: US 2026/0107541 A1
(43) Pub. Date: Apr. 16, 2026

(54) SEMICONDUCTOR STRUCTURE AND METHOD FOR FORMING A SEMICONDUCTOR STRUCTURE

(71) Applicant: Taiwan Semiconductor Manufacturing Company, Ltd., Hsinchu (TW)

(72) Inventors: Chun-Yi CHOU, Hsinchu City (TW); Guan-Lin CHEN, Baoshan Township (TW); Shi-Ning JU, Hsinchu City (TW); Kuo-Cheng CHIANG, Zhubei City (TW); Chih-Hao WANG, Baoshan Township (TW)

(73) Assignee: Taiwan Semiconductor Manufacturing Company, Ltd., Hsinchu (TW)

(21) Appl. No.: 18/917,698

(22) Filed: Oct. 16, 2024

(51) Int. Cl. H01L 29/66; H01L 29/06; H01L 29/423; H01L 29/775; H01L 29/786

(52) U.S. Cl. CPC H10D 64/018; H10D 30/014; H10D 30/43; H10D 30/6735; H10D 30/6757; H10D 62/121; H10D 64/017; H10D 30/6736

(57) ABSTRACT

A method for forming a semiconductor structure includes alternately forming a plurality of channel layers and a plurality of sacrificial layers over a substrate. The method includes forming a top sacrificial layer over the channel layers and the sacrificial layers. The method includes forming a source/drain trench through the top sacrificial layer, the channel layers, and the sacrificial layers. The method includes recessing the top sacrificial layer and the sacrificial layers through the source/drain trench so that a first width of the top sacrificial layer is less than a second width of the sacrificial layers. The method includes forming a plurality of inner spacers on sidewalls of the top sacrificial layer and sidewalls of the sacrificial layers. The method includes replacing the top sacrificial layer and the sacrificial layers with a gate structure.

### BACKGROUND

Semiconductor devices are widely used in various electronic applications, such as personal computers, mobile phones, digital cameras, and other electronic equipment. As the size of semiconductor devices shrinks, the difficulty of manufacturing semiconductor devices has also increased significantly. Defects may occur during the process of manufacturing semiconductor devices, and these defects may cause failure, or they may cause the performance of the semiconductor devices to suffer. Therefore, further improvements in semiconductor devices are required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1D illustrate perspective views of various stages of manufacturing a semiconductor structure in accordance with some embodiments of the present disclosure.

FIGS. 2A to 2H illustrate cross-sectional views of various stages of manufacturing a semiconductor structure in accordance with some embodiments of the present disclosure.

FIG. 3 illustrates a cross-sectional view of a semiconductor structure in accordance with some embodiments of the present disclosure.

FIG. 4 illustrates a cross-sectional view of a semiconductor structure in accordance with some embodiments of the present disclosure.

FIGS. 5A to 5H illustrate cross-sectional views of various stages of manufacturing a semiconductor structure in accordance with some embodiments of the present disclosure.

FIG. 6 illustrates a cross-sectional view of a semiconductor structure in accordance with some embodiments of the present disclosure.

FIG. 7 illustrates a cross-sectional view of a semiconductor structure in accordance with some embodiments of the present disclosure.

FIG. 8 illustrates a cross-sectional view of a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. For avoidance of doubts, the X-direction, the Y-direction, and the Z-direction in the figures are perpendicular to one another and are used consistently.

The nanostructure transistor (e.g. nanosheet transistor, nanowire transistor, multi-bridge channel, nano-ribbon FET, gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Semiconductor structures and methods for forming a semiconductor structure are described in accordance with some embodiments of the present disclosure. The semiconductor structure may be a gate-all-around (GAA) transistor structure. The method may include recessing the top layer of the sacrificial layers deeper than the other sacrificial layers, so that the subsequently formed top inner spacers can be enlarged to separate the top gate structure and the source/drain structure, leading to effective capacitance (Ceff) reduction.

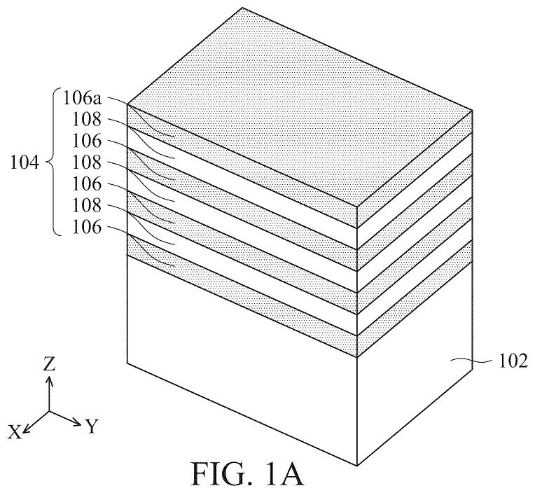

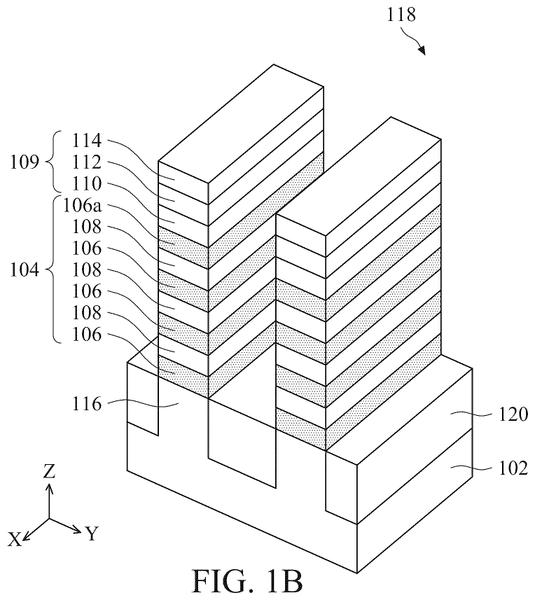

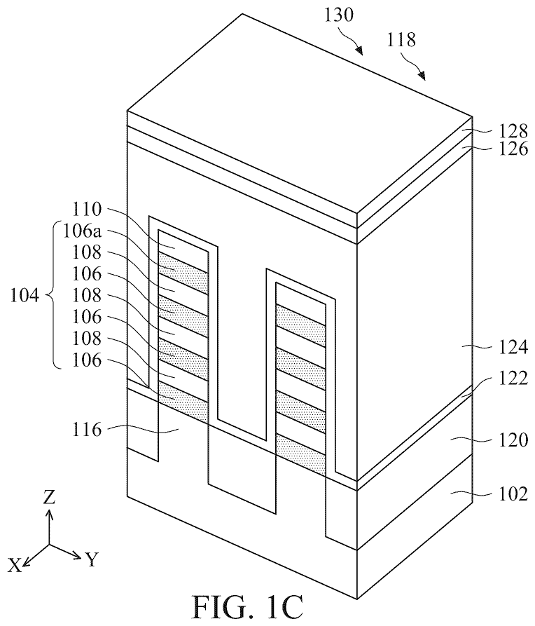

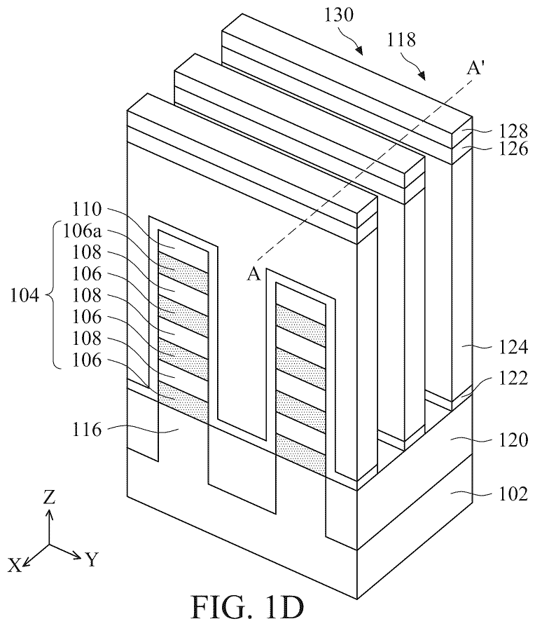

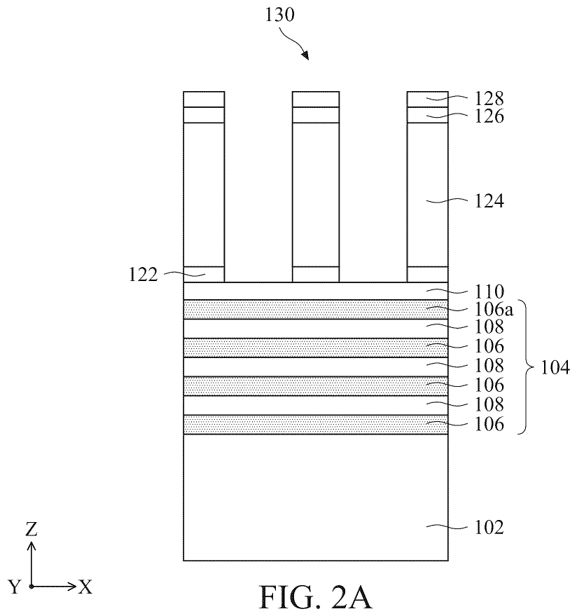

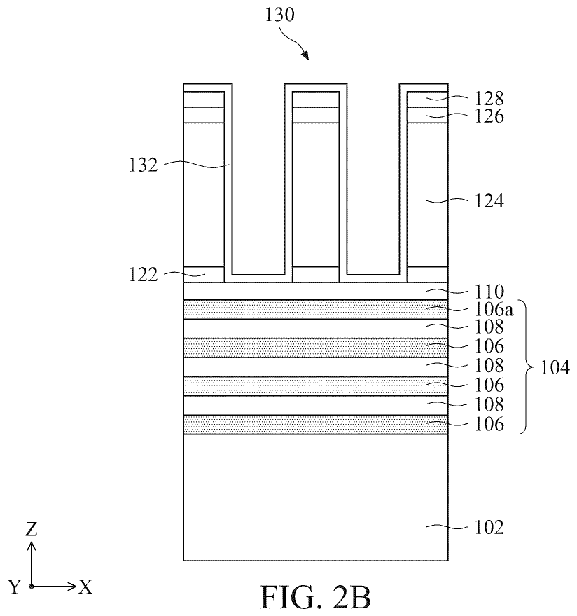

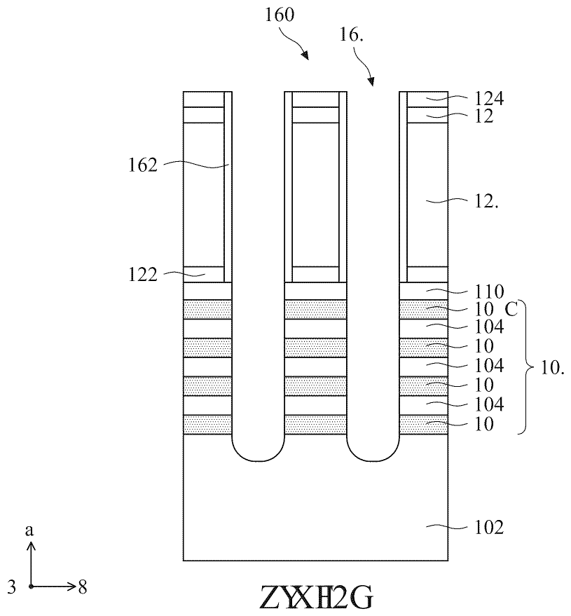

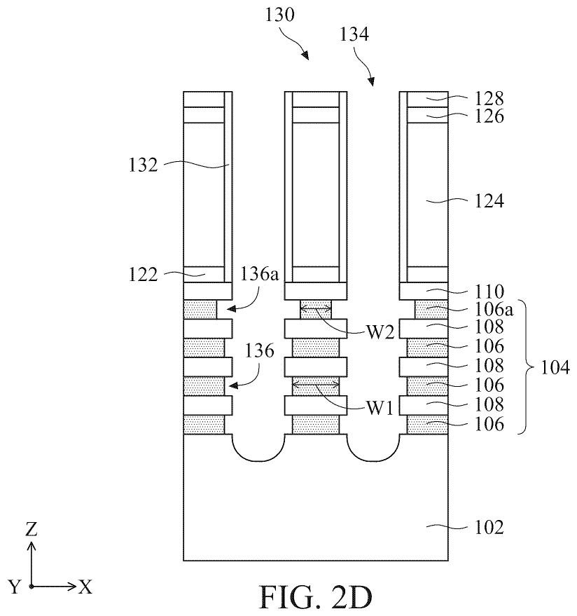

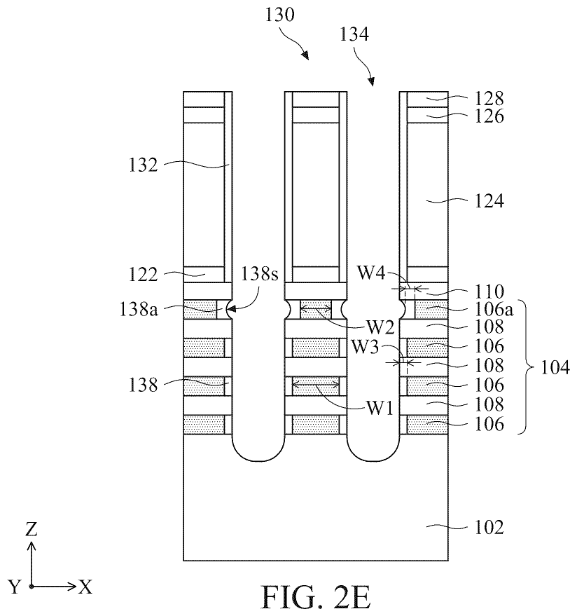

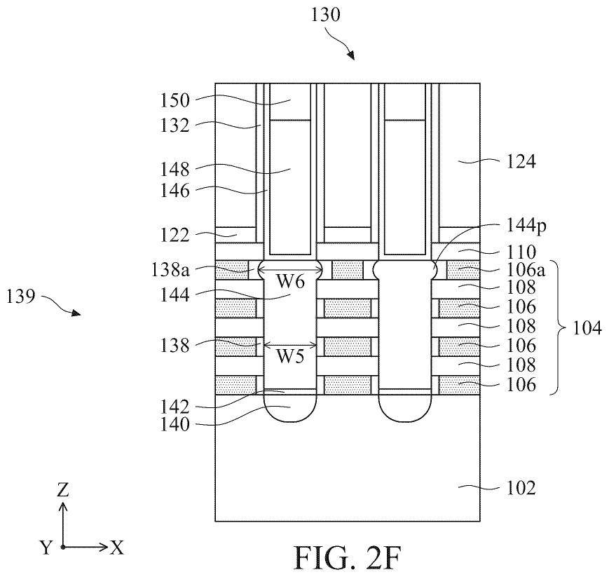

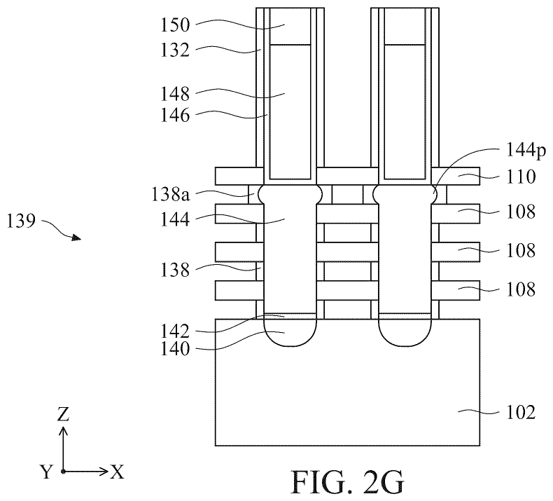

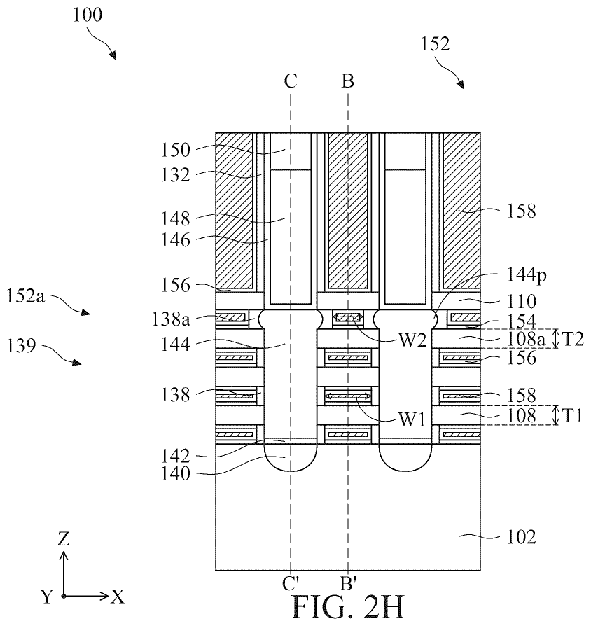

FIGS. 1A to 1D illustrate perspective views of various stages of manufacturing a semiconductor structure 100 in accordance with some embodiments of the present disclosure. FIGS. 2A to 2H illustrate cross-sectional views of various stages of manufacturing the semiconductor structure 100 in accordance with some embodiments of the present disclosure. FIGS. 2A to 2H illustrate cross-sectional views taken along line A-A′ shown in FIG. 1D. Additional features can be added to the semiconductor structure 100. Some of the features described below can be replaced or eliminated for different embodiments. To simplify the diagram, only a portion of the semiconductor structure 100 is illustrated.

As illustrated in FIG. 1A, a stack 104 is formed over a substrate 102, in accordance with some embodiments. The substrate 102 may be a semiconductor wafer, such as a silicon wafer. The substrate 102 may be formed of elementary semiconductor materials, compound semiconductor materials, alloy semiconductor materials, the like, or a combination thereof. Examples of the elementary semiconductor materials may include crystal silicon, polycrystalline silicon, amorphous silicon, germanium, diamond, the like, or a combination thereof. Examples of the compound semiconductor materials may include silicon carbide, gallium nitride, gallium arsenic, gallium phosphide, indium phosphide, indium arsenide, indium antimonide, the like, or a combination thereof. Examples of the alloy semiconductor materials may include SiGe, GaAsP, AlInAs, AlGaAs, GaInAs, GaInP, GaInAsP, the like, or a combination thereof. Alternatively, the substrate 102 may be semiconductor on insulator, including a silicon-on-insulator (SOI), a germanium-on-insulator (GeOI), the like, or a combination thereof.

The substrate 102 may include one or more well regions for forming different types of devices. The well regions may include n-type well regions doped with n-type dopants or p-type well regions doped with p-type dopants, and may be formed by using ion implantation, thermal diffusion, or another suitable process. For example, the P-type dopants may include boron (B), boron difluoride (BF₂), gallium (Ga), or a combination thereof, and the N-type dopants may include phosphorus (P), arsenic (As), antimony (Sb), or a combination thereof.

The stack 104 may include a plurality of sacrificial layers 106 and a top sacrificial layer 106a interleaved by a plurality of channel layers 108. The top sacrificial layer 106a may be formed over the sacrificial layers 106 and the channel layers 108. The sacrificial layers 106, the top sacrificial layer 106a, and the channel layers 108 may be alternatingly stacked in the Z-direction. The sacrificial layers 106, the top sacrificial layer 106a and the channel layers 108 may each be independently formed by using low-pressure chemical vapor deposition (LPCVD), ultra-high vacuum CVD (UHV-CVD), molecular beam epitaxy (MBE), metal organic chemical vapor deposition (MOCVD), vapor phase epitaxy (VPE), the like, or a combination thereof.

The sacrificial layers 106 and the channel layers 108 may be made of different materials with different etching rates, and the top sacrificial layer 106a and the channel layers 108 may be made of different materials with different etching rates. For example, the sacrificial layers 106 and the top sacrificial layer 106a may be formed of silicon germanium (SiGe) or germanium tin (GeSn), and the channel layers 108 may be formed of silicon.

The germanium concentration of the sacrificial layers 106 may be in a range of about 20% to about 26%. The germanium concentration of the top sacrificial layer 106a may be in a range of about 30% to about 55%. If the germanium concentration of the sacrificial layers 106 and the top sacrificial layer 106a are too low, the required etch selectivity between the sacrificial layers 106 and the channel layers 108 and the required etch selectivity between the top sacrificial layer 106a and the channel layers 108 would not be achieved, so that the sacrificial layers 106 and the top sacrificial layer 106a may not be selectively removed without substantially etching the channel layers 108. If the germanium concentration is too high, the number of germanium diffusing into the channel layers 108 would increase, resulting in more impurity in the channel layers 108. Consequently, semiconductor device performance would be degraded. In addition, the lattice mismatch between the sacrificial layers 106 and the channel layers 108 and the lattice mismatch between the top sacrificial layer 106a and the channel layers 108 would be too large, which would introduce defects.

The germanium concentration of the top sacrificial layer 106a may be greater than the germanium concentration of each of the sacrificial layers 106. In some embodiments, the germanium concentration of the top sacrificial layer 106a is about 10% to about 35% greater than the germanium concentration of each of the sacrificial layers 106. If the difference of the germanium concentrations of the top sacrificial layer 106a and the sacrificial layers 106 is too large, a large lattice mismatch between the top sacrificial layer 106a and the channel layers 108 would occur. If the difference of the germanium concentrations of the top sacrificial layer 106a and the sacrificial layers 106 is too small, the etching rate difference between the top sacrificial layer 106a and the sacrificial layers 106 may not be large enough.

It should be noted that three layers of the sacrificial layers 106 and three layers of the channel layers 108 as shown in FIG. 1A are for illustrative purposes only, and more or less numbers of layers may be alternately formed. The number of layers may depend on the desired number of channels members for the semiconductor structure 100, such as 2 to 10.

Then, as illustrated in FIG. 1B, a patterned hard mask layer 109 is formed over the stack 104, in accordance with some embodiments. The patterned hard mask layer 109 may be a multi-layer structure, which may include a hard mask layer 110, a hard mask layer 112 over the hard mask layer 110, and a hard mask layer 114 over the hard mask layer 112. The stack 104 may be patterned to form fin structures 118 using a photolithography process and an etch process with the patterned hard mask layer 109. Each of the fin structures 118 may extend lengthwise in the X-direction and may extend vertically in the Z-direction, and the fin structures 118 may be arranged in the Y-direction. Each of the fin structures 118 may include a base portion 116 and the semiconductor material stack of the sacrificial layers 106, the top sacrificial layer 106a, and the channel layers 108 thereon.

In some embodiments, the hard mask layer 110 includes SiCN, the hard mask layer 112 includes nitride, and the hard mask layer 114 includes oxide. The hard mask layer 114 may be made of silicon oxide, which may be formed by using a thermal oxidation process, a chemical vapor deposition (CVD) process, or another suitable process. The hard mask layer 112 may be made of silicon nitride, which may be formed by using a CVD process, including LPCVD, plasma-enhanced CVD (PECVD), another suitable process, or a combination thereof.

The photolithography process may include photoresist coating (e.g., spin-on coating), soft baking, mask aligning, exposure, post-exposure baking, photoresist developing, rinsing, drying (e.g., spin-drying and/or hard baking), another suitable photolithography techniques, or a combination thereof. The etching process may include a dry etching (e.g., reactive ion etching (RIE)) process, a wet etching process, or a combination thereof. It should be noted that two fin structures 118 as shown in FIG. 1B are for illustrative purposes only, and more fin structures may be formed, such as three or more fin structures.

Then, an isolation structure 120 is formed in the trenches between the fin structures 118 to electrically isolate adjacent fin structures 118, in accordance with some embodiments. The isolation structure 120 may be a shallow trench isolation (STI) structure. The isolation structure 120 may be formed by filling an insulating material, including silicon oxide, silicon nitride, silicon oxynitride (SiON), SiOCN, SiCN, fluoride-doped silicate glass (FSG), other low-k dielectric materials, or a combination thereof. The insulating material may be formed by a deposition process, including a CVD (such as flowable CVD (FCVD), PECVD, or LPCVD) process, a spin-on-glass process, another suitable process, or a combination thereof.

A planarization process, including a grinding process, a chemical mechanical polishing (CMP) process, an etching process, another suitable process, or a combination thereof, may be performed to partially remove the patterned hard mask layer 109 and the insulating material. The hard mask layers 112 and 114 may be removed and the hard mask layer 110 may be remained. Then, the insulating material may be etched back by an etching process to form the isolation structure 120 and to expose the stack 104. The etching process may include a dry etching process, a wet etching process, or a combination thereof.

The isolation structure 120 may be a multi-layer structure, for example, having one or more liner layers. The liner layer may be formed in the trenches before filling the insulating material. The liner layer may be formed of silicon nitride or another suitable material and may be formed by using a thermal oxidation process, a CVD process (e.g., a FCVD process, a PECVD process, or a LPCVD process), an atomic layer deposition (ALD) process (e.g., a plasma enhanced ALD (PEALD) process), another suitable process, or a combination thereof.

Then, as illustrated in FIG. 1C, a dummy gate structure 130 is formed across the fin structures 118 and over the isolation structure 120, in accordance with some embodiments. The dummy gate structure 130 may each include a dummy gate dielectric layer 122 and a dummy gate electrode layer 124 over the dummy gate dielectric layer 122. The dummy gate dielectric layer 122 and the dummy gate electrode layer 124 may be replaced by the following steps to form a real gate structure with a high-k dielectric layer and a metal gate electrode layer.

The dummy gate dielectric layer 122 may be conformally formed over the fin structure 118 to have substantially uniform thickness over various regions. The dummy gate dielectric layer 122 may be made of dielectric materials, including silicon oxide, silicon nitride, silicon oxynitride (SiON), HfO₂, HfZrO, HfSiO, HfTiO, HfAlO, another suitable dielectric material, or a combination thereof. Alternatively, the dummy gate dielectric layer 122 may be made of a high-k dielectric layer (e.g., the dielectric constant is greater than 3.9), including hafnium oxide (HfO₂), LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, another suitable high-k dielectric material, or a combination thereof. The dummy gate dielectric layer 122 may be formed using an oxidation process (e.g., a dry oxidation process or a wet oxidation process), a CVD process, an ALD process, a physical vapor deposition (PVD) process (e.g., a vacuum evaporation process or a sputtering process), another suitable method, or a combination thereof.

The dummy gate electrode layer 124 may be made of conductive materials, including polycrystalline-silicon (poly-Si), poly-crystalline silicon-germanium (poly-SiGe), metallic nitrides, metallic silicides, metals, another suitable conductive material, or a combination thereof. The dummy gate electrode layer 124 may be formed using CVD, PVD, another suitable method, or a combination thereof.

Then, gate-top hard mask layers 126 and 128 are formed over the dummy gate structure 130, in accordance with some embodiments. The gate-top hard mask layer 126 may include oxide, such as silicon oxide, which may be formed by a thermal oxidation process, a CVD process, or another suitable process. The gate-top hard mask layer 128 may include nitride, such as silicon nitride, which may be formed by using a CVD process, including LPCVD, PECVD, or another suitable process.

The material of dummy gate dielectric layer 122 and the material of dummy gate electrode layer 124 may be patterned to form the dummy gate structure 130 using a photolithography process and an etch process with the gate-top hard mask layers 126 and 128, in accordance with some embodiments. The etching process may include a dry etching (e.g., RIE) process, a wet etching process, or a combination thereof. After the patterning, the dummy gate structure 130 may be formed over channel regions, as illustrated in FIGS. 1D and 2A.

Then, as illustrated in FIG. 2B, a spacer layer 132 is conformally formed over the hard mask layer 110 and the dummy gate structure 130, in accordance with some embodiments. The spacer layer 132 may be made of dielectric materials, including silicon oxide, silicon nitride, silicon oxynitride, silicon carbonitride, silicon oxycarbide, silicon oxycarbonitride, another suitable material, or a combination thereof. The spacer layer 132 may include a single layer or a multi-layer structure. The spacer layer 132 may be formed by a deposition process, including a CVD (such as FCVD, PECVD, or LPCVD) process, a spin-on-glass process, another suitable process, or a combination thereof.

Then, as illustrated in FIG. 2C, the spacer layer 132 is etched by an etching process to form a pair of spacer layers 132 on opposite sidewalls of the dummy gate structure 130, in accordance with some embodiments. The etching process may include a dry etching (e.g., RIE) process, a wet etching process, or a combination thereof. In some embodiments, the sacrificial layers 106, the top sacrificial layer 106a, and the channel layers 108 are partially removed in the etching process using the spacer layers 132 as the mask to form a source/drain trench 134. The source/drain trench 134 may extend vertically through the hard mask layer 110 and the stack 104 and may partially extend into the substrate 102. The bottom surface of the source/drain trench 134 may be concave.

After the etching process, the sidewall of the source/drain trench 134 may be substantially aligned with the sidewall of the spacer layers 132. The sidewall of the sacrificial layers 106 may be substantially vertically aligned with the sidewall of the channel layer 108, and the sidewall of the top sacrificial layers 106a may be substantially vertically aligned with the sidewall of the channel layer 108 and may be substantially vertically aligned with the sidewall of the hard mask layer 110.

Then, as illustrated in FIG. 2D, the sacrificial layers 106 and the top sacrificial layer 106a are laterally etched from the source/drain trench 134 to form recesses 136 and top recesses 136a, respectively, while the channel layers 108 are not significantly etched, in accordance with some embodiments. The outer portions of the sacrificial layers 106 and the top sacrificial layer 106a may be removed, and the inner portions of the sacrificial layers 106 and the top sacrificial layer 106a under the dummy gate structure 130 may remain.

The lateral etching of the sacrificial layers 106 and the top sacrificial layer 106a may be a selective dry etching process, a selective wet etching process, or a combination thereof. The lateral etching may etch silicon germanium layers having different germanium concentrations at different etch rates. In particular, the lateral etching may etch a silicon germanium layer with a higher germanium concentration at a higher rate than it etches a silicon germanium layer with a lower germanium concentration. In some embodiments where the lateral etching is a selective dry etching process, the lateral etching includes one or more fluorine-based etchants, including fluorine gas, hydrofluorocarbons, another suitable etchant, or a combination thereof. In some embodiments where the lateral etching is a selective wet etching process, the lateral etching includes an APM etch (e.g., ammonia hydroxide-hydrogen peroxide-water mixture) or another suitable etchant.

Since the top sacrificial layer 106a has a germanium concentration higher than the germanium concentration of the sacrificial layers 106, the lateral etching may etch the top sacrificial layer 106a at a higher rate than it etches the sacrificial layers 106. The amount of the top sacrificial layer 106a may be removed more than the amount of one of the sacrificial layers 106. Therefore, the top recesses 136a may be enlarged with larger widths than the recesses 136 in the X-direction.

After the lateral etching process, the sidewalls of the etched sacrificial layers 106 and the etched top sacrificial layer 106a may be not aligned with the sidewalls of the channel layers 108. The sidewalls of the channel layers 108 may protrude laterally beyond the sidewalls of the sacrificial layers 106 and may protrude laterally beyond the sidewalls of the top sacrificial layer 106a.

The sacrificial layers 106 below the top sacrificial layer 106a may have approximately the same width, such as a width W1. The etched top sacrificial layer 106a may have a width W2, which is less than the width W1 of the etched sacrificial layers 106. In some embodiments, the width W2 of the top sacrificial layer 106a is about 0.3 nm to about 3 nm less than the width W1 of the sacrificial layers 106.

Then, as illustrated in FIG. 2E, a plurality of inner spacers 138 are formed in the recesses 136, and a plurality of top inner spacers 138a are formed in the top recesses 136a, in accordance with some embodiments. The inner spacers 138 and the top inner spacers 138a may provide a barrier between subsequently formed source/drain structure and gate structure. Since the top recesses 136a are deeper than the recesses 136, the top inner spacers 138a may have a larger width than the inner spacers 138, thereby providing a longer distance between subsequently formed source/drain structure and gate structure, leading to the effective capacitance (Ceff) reduction.

The inner spacers 138 and the top inner spacers 138a may be made of dielectric material, including silicon oxide (SiO₂), silicon nitride (SiN), silicon carbide (SiC), silicon oxynitride (SiON), silicon carbon nitride (SiCN), silicon oxide carbonitride (SiOCN), another suitable material, or a combination thereof. The inner spacers 138 and the top inner spacers 138a may be formed by a deposition process. The deposition process may include a CVD process (such as a LPCVD process, a PECVD process, a sub-atmospheric chemical vapor deposition (SACVD) process, or a FCVD process), an ALD process, another suitable method, or a combination thereof.

Each of the inner spacers 138 may have a substantially straight inner sidewall and a substantially straight outer sidewall. The outer sidewalls of the inner spacers 138 may be substantially aligned with the sidewalls of the channel layers 108. Each of the top inner spacers 138a may have a substantially straight inner sidewall and a dishing outer sidewall. In some embodiments, the top inner spacers 138a have a concave sidewall 138s which is opposite to the sidewall adjoining the top sacrificial layer 106a. The top edge of the concave sidewall 138s may be in contact with the sidewall of the hard mask layer 110, and the bottom edge of the concave sidewall 138s may be in contact with the sidewall of one of the channel layers 108. The width of the top sacrificial layer 106a may decrease from the top to the middle of the top sacrificial layer 106a and may decrease from the bottom to the middle of the top sacrificial layer 106a.

The hard mask layer 110 may protrude laterally beyond the middle portion of the top inner spacers 138a when viewed from above, or from a direction that is parallel to the sidewall of the hard mask layer 110. The channel layers 108 may protrude laterally beyond the middle portion of the top inner spacers 138a when viewed from above, or from a direction that is parallel to the sidewall of the channel layers 108.

The distance between the inner sidewalls of adjacent inner spacers 138 may be substantially equal to the width W1 of the sacrificial layers 106. The distance between the inner sidewalls of adjacent top inner spacers 138a may be substantially equal to the width W2 of the top sacrificial layer 106a. The distance between the inner sidewalls of adjacent inner spacers 138 may be greater than the distance between the inner sidewalls of adjacent top inner spacers 138a. In some embodiments, the sacrificial layers 106 have the substantially same width, while the top sacrificial layer 106a is narrower than any one of the sacrificial layers 106.

In particular, the top inner spacers 138a may have a narrowest width W4 at the middle portion (in the Z-direction) of the top inner spacers 138a. The inner spacers 138 may have a width W3, which is less than the width W4 of the top inner spacers 138a. In some embodiments, the width W4 of the top inner spacers 138a is about 0.3 nm to about 3 nm greater than the width W3 of the inner spacers 138. If the width difference is too large, the space for subsequently formed gate structure would be too small, resulting in increasing difficulty of gate control. If the width difference is too small, there would be not enough distance between subsequently formed source/drain structure and gate structure, leading to the effective capacitance (Ceff) penalty. The sacrificial layers 106 and the top sacrificial layer 106a may have approximately the same thickness.

Then, as illustrated in FIG. 2F, a source/drain structure 139 is formed in the source/drain trench 134, in accordance with some embodiments. The source/drain structure(s) 139 may refer to a source or a drain, individually or collectively dependent upon the context. The source/drain structure 139 may include a first epitaxial layer 140, a bottom isolation layer 142 over the epitaxial layer 140, and a second epitaxial layer 144 over the bottom isolation layer 142.

In some embodiments, the first epitaxial layer 140 is formed over the bottom surface of the source/drain trench 134, such that the first epitaxial layer 140 extends into the substrate 102 in the Z-direction and is in contact with the substrate 102. In some embodiments, the first epitaxial layer 140 is substantially free of dopants. The first epitaxial layer 140 may include Si, Ge, SiGe, another suitable semiconductor material, or a combination thereof. In some embodiments, the first epitaxial layer 140 includes silicon that is substantially free of n-type dopants and p-type dopants. The first epitaxial layer 140 may be epitaxially grown by using an epitaxial growth process, including MBE, CVD, MOCVD, LPCVD, PECVD, UHV-CVD, remote plasma CVD (RPCVD), ALD, VPE, another suitable method, or a combinations thereof.

The bottom isolation layer 142 may be formed over the first epitaxial layer 140. In some embodiments, the bottom isolation layer 142 may be a single layer or a multi-layer structure. In some embodiments, the bottom isolation layer 142 may be made of dielectric material, including Si₃N₄, SiO₂, SiC, SiOC, SiON, SiCN, SiOCN, high-k dielectric, another suitable material, or a combination thereof. In some embodiments, the bottom isolation layer 142 may be deposited by using CVD, high density plasma CVD (HDPCVD), MOCVD, RPCVD, PECVD, LPCVD, atomic layer CVD (ALCVD), atmospheric pressure CVD (APCVD), PVD, ALD, another suitable method, or combinations thereof.

The second epitaxial layer 144 may be formed over the bottom isolation layer 142. The second epitaxial layer 144 may be formed by using epitaxial growth process, including MBE, CVD, MOCVD, LPCVD, PECVD, UHV-CVD, RPCVD, ALD, VPE, another suitable method, or a combination thereof. In some embodiments, the second epitaxial layer 144 is grown from the channel layers 108. The top surface of the second epitaxial layer 144 may be higher than, lower than, or substantially aligned with the bottom surface of the hard mask layer 110.

The source/drain structure 139 is used for p-type FETs (PFETs) or n-type FETs (NFETs), and thus may be referred to as p-type source/drain structure or n-type source/drain structure, respectively. The second epitaxial layer 144 may be doped in-situ during the epitaxial process or doped ex-situ by using a junction implant process, for example. One or more annealing processes may be performed to activate the dopants in the second epitaxial layer 144. The annealing processes may include rapid thermal annealing (RTA), laser annealing process, another suitable process, or a combination thereof.

For the p-type source/drain structure, the second epitaxial layer 144 may be doped with p-type dopants and may include epitaxially-grown material, including boron-doped SiGe, boron-doped SiGeC, boron-doped Ge, boron-doped Si, boron and carbon doped SiGe, another suitable material, or a combination thereof. For the n-type source/drain structure, the second epitaxial layer 144 may be doped with n-type dopants and may include epitaxially-grown material including SiP, SiC, SiPC, SiAs, Si, another suitable material, or a combination thereof.

The source/drain structure 139 may have a width W5 at the middle and a width W6 at the top in the X-direction. In particular, the source/drain structure 139 may have the width W5 between the inner spacers 138 or between the channel layers 108 and may have the width W6 between the top inner spacers 138a in the X-direction. The width W6 may be greater than the width W5.

The second epitaxial layer 144 of the source/drain structure 139 may have a protrusion 144p adjoining the top inner spacers 138a. The sidewall of the protrusion 144p of the second epitaxial layer 144 may have a shape corresponding to that of the sidewall of the top inner spacers 138a. The sidewall of the protrusion 144p of the second epitaxial layer 144 may be convex.

The protrusion 144p of the second epitaxial layer 144 may be surrounded by the top inner spacers 138a. The protrusion 144p of the second epitaxial layer 144 may protrude laterally beyond the sidewall of the hard mask layer 110 when viewed from above, or from a direction that is parallel to the sidewall of the hard mask layer 110. The protrusion 144p of the second epitaxial layer 144 may protrude laterally beyond the sidewall of the channel layers 108 when viewed from above, or from a direction that is parallel to the sidewall of the channel layers 108. The protrusion 144p of the second epitaxial layer 144 may protrude laterally beyond the sidewall of the inner spacers 138 when viewed from above, or from a direction that is parallel to the sidewall of the inner spacers 138.

Then, an etch stop layer 146 is conformally formed over the source/drain structure 139 and is formed over the sidewalls of the hard mask layer 110 and the sidewalls of the spacer layers 132, in accordance with some embodiments. The etch stop layer 146 may be made of silicon nitride, silicon oxide, silicon oxynitride (SiON), another suitable material, or a combination thereof. The etch stop layer 146 may be formed using a CVD process (e.g., a PECVD process or a MOCVD process), an ALD process (e.g., a PEALD process), a PVD process (e.g., a vacuum evaporation process or a sputtering process), another suitable processes, or a combination thereof.

Next, an inter-layer dielectric (ILD) structure 148 is formed over the etch stop layer 146, in accordance with some embodiments. The ILD structure 148 may include a material that is different from that of the etch stop layer 146. The ILD structure 148 may be a multi-layer structure made of multiple dielectric materials, including silicon oxide, silicon oxycarbide, silicon oxycarbonitride, silicon nitride, silicon oxynitride, tetraethyl orthosilicate (TEOS) oxide, phosphosilicate glass (PSG), borophosphosilicate glass (BPSG), low-k dielectric materials, another suitable dielectric material, or a combination thereof. Examples of low-k dielectric materials may include fluorinated silica glass (FSG), carbon doped silicon oxide, amorphous fluorinated carbon, parylene, bis-benzocyclobutenes (BCB), polyimide, another suitable materials, or a combination thereof. The ILD structure 148 may be formed using a CVD (such as flowable CVD (FCVD), PECVD, or LPCVD) process, a spin-on coating process, another suitable processes, or a combination thereof.

Then, a planarization process is performed on the ILD structure 148 until the top surface of the dummy gate structure 130 is exposed, in accordance with some embodiments. The planarization process may include a grinding process, a chemical mechanical polishing (CMP) process, an etching process, another suitable process, or a combination thereof. After the planarization process, the top surface of the dummy gate structure 130 may be substantially aligned with the top surfaces of the spacer layers 132, the etch stop layer 146, and the ILD structure 148.

Next, the ILD structure 148 is recessed and a protection layer 150 is deposited over the ILD structure 148 to protect the ILD structure 148 from subsequent etching processes, in accordance with some embodiments. The protection layer 150 may be made of a material that is the same as or similar to that of the etch stop layer 146. The protection layer 150 may be made of Si₃N₄, SiCN, SiOCN, SiOC, a metal oxide such as HrO₂, ZrO₂, hafnium aluminum oxide, hafnium silicate, another suitable material, or a combination thereof. The protection layer 150 may be formed by using CVD, PVD, ALD, another suitable method, or a combination thereof. The protection layer 150 may be surrounded by the etch stop layer 146.

Then, as illustrated in FIG. 2G, the dummy gate structure 130 is removed using an etching process, in accordance with some embodiments. The etching process may include a dry etching process, a wet etching process, or a combination thereof. Afterwards, the sacrificial layers 106 and the top sacrificial layer 106a are removed to form a plurality of gate openings between the channel layers 108 and between the top layer of the channel layers 108 and the hard mask layer 110, in accordance with some embodiments. The channel layers 108 may be released.

The removal process may include a selective etching process, which may remove the sacrificial layers 106 and the top sacrificial layer 106a and remain the channel layers 108 as nanostructures 108. The nanostructures 108 may include nanowires, nanorods, nanosheets, or another suitable nanostructures. The selective etching process may include a selective wet etching process, a selective dry etching process, or a combination thereof. For example, the selective etching process may be a plasma-free dry chemical etching process. The etchant of the dry chemical etching process may include radicals, including HF, NF₃, NH₃, H₂, another suitable etchant, or a combination thereof.

Then, as illustrated in FIG. 2H, a gate structure 152 is formed in such a way that it is wrapped around the channel layers 108 and the hard mask layer 110, in accordance with some embodiments. The portion of the gate structure 152 between the top layer of the channel layers 108 and the hard mask layer 110 may be referred to as an upper gate structure 152a. The gate structure 152 may include an interfacial layer 154, a high-k dielectric layer 156, and a gate electrode layer 158. The channel layers 108 may be surrounded and in contact with the interfacial layer 154. The interfacial layer 154 may be surrounded by the high-k dielectric layer 156. The hard mask layer 110 may be surrounded by the high-k dielectric layer 156. The high-k dielectric layer 156 may be surrounded by the gate electrode layer 158.

The interfacial layer 154 may be made of silicon oxide, and may be formed by using a thermal oxidation process. The high-k dielectric layer 156 may be made of dielectric material, including HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, another suitable high-k dielectric material, or a combination thereof. The high-k dielectric layer 156 may be formed by using a CVD process (e.g., a FCVD process, a PECVD process, or a LPCVD process), an ALD process, another suitable method, or a combination thereof.

The gate electrode layer 158 may include one or more work function layers and a metal fill layer. The work function layers may be made of metal materials. In some embodiments, the metal materials are P-work-function metals, including titanium nitride (TiN), tungsten nitride (WN), tantalum nitride (TaN), ruthenium (Ru), another suitable material, or a combination thereof. In some embodiments, the metal materials are N-work-function metals, including tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), another suitable material, or a combination thereof. The work function layers may be formed by using a CVD process (e.g., a FCVD process, a PECVD process, or a LPCVD process), an ALD process, another suitable method, or a combination thereof.

The metal fill layer may be made of one or more conductive materials, including polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. The metal fill layer may be formed by using a CVD process (e.g., a FCVD process, a PECVD process, or a LPCVD process), an ALD process, electroplating, another suitable method, or a combination thereof.

The gate structure 152 between the channel layers 108 may have the width W1 in the X-direction. The upper gate structure 152a between the top layer of the channel layers 108 and the hard mask layer 110 may have the width W2 in the X-direction. The width W2 of the upper gate structure 152a may be less than the W1 of the gate structure 152. In some embodiments, the width W2 of the upper gate structure 152a is about 0.3 nm to about 3 nm less than the width W1 of the gate structure 152. If the width difference is too large, it would be difficult for gate control. If the width difference is too small, there would be not enough distance between the source/drain epitaxial structure 139 and the upper gate structure 152a, resulting in the effective capacitance (Ceff) penalty.

Then, a planarization process is performed until the protection layer 150 is exposed, in accordance with some embodiments. The planarization process may include a grinding process, a CMP process, an etching process, another suitable process, or a combination thereof. The semiconductor structure 100 may be formed.

The channel layers 108 between the gate structure 152 may have a thickness T1 in the Z-direction, and the top layer of the channel layers 108 (which may be referred to as a top channel layer 108a) adjacent to the upper gate structure 152a may have a thickness T2 in the Z-direction. As illustrated in FIG. 2H, the thickness T1 of the channel layers 108 may be substantially equal to the thickness T2 of the top channel layer 108a.

In some other embodiments, the thickness T2 of the top channel layer 108a is thinner than the thickness T1 of the channel layers 108. The thickness T2 of the top channel layer 108a may be about 0.1 nm to about 1.5 nm thinner than the thickness T1 of the channel layers 108. With this thickness difference, short channel effect (SCE) degradation induced by the upper gate structure 152a being narrower than the gate structure 152 can be recovered.

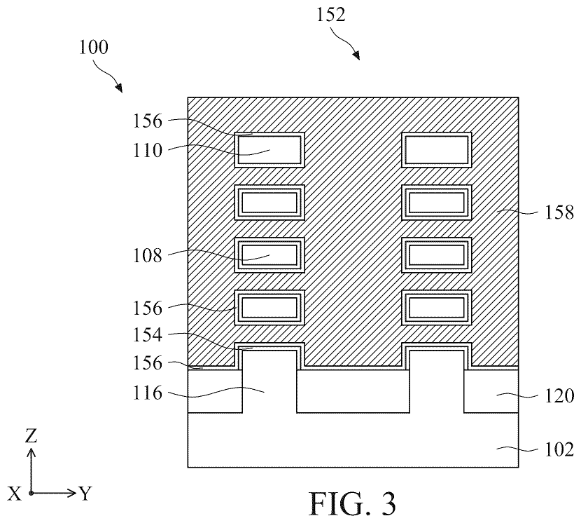

FIG. 3 illustrates a cross-sectional view of the semiconductor structure 100 shown along line B-B′ in FIG. 2H in accordance with some embodiments of the present disclosure.

As illustrated in FIG. 3, the isolation structure 120 may be formed between the base portions 116. The channel layers 108 may be stacked over the base portions 116 and may each be wrapped around by the interfacial layer 154. The interfacial layer 154 may be wrapped around by the high-k dielectric layer 156. The hard mask layer 110 may be stacked over the channel layers 108 and may be wrapped around by the high-k dielectric layer 156. The gate electrode layer 158 may be formed to cover the isolation structure 120, the base portions 116, and may wrap around the high-k dielectric layer 156. The gate electrode layer 158 may wrap around the channel layers 108 and the hard mask layer 110. The gate electrode layer 158 may fill the gaps between the channel layers 108 and between the channel layers 108 and the hard mask layer 110 form a GAA transistor structure.

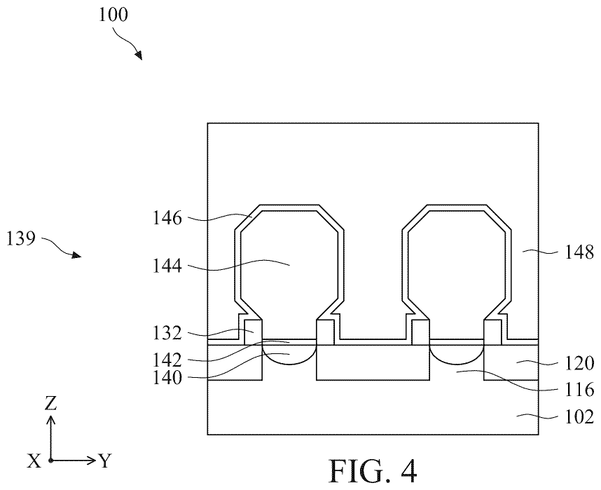

FIG. 4 illustrates a cross-sectional view of the semiconductor structure 100 shown along line C-C′ in FIG. 2H in accordance with some embodiments of the present disclosure.

As illustrated in FIG. 4, the spacer layers 132 may be formed over the isolation structure 120 and on opposite sides of the source/drain structure 139. The etch stop layer 146 may be formed over the isolation structure 120 and to cover the source/drain structure 139 and the spacer layers 132. The ILD structure 148 may be formed to cover the etch stop layer 146.

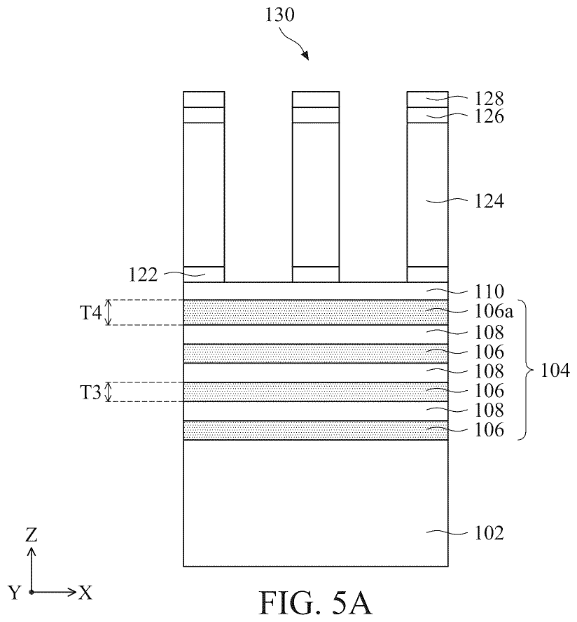

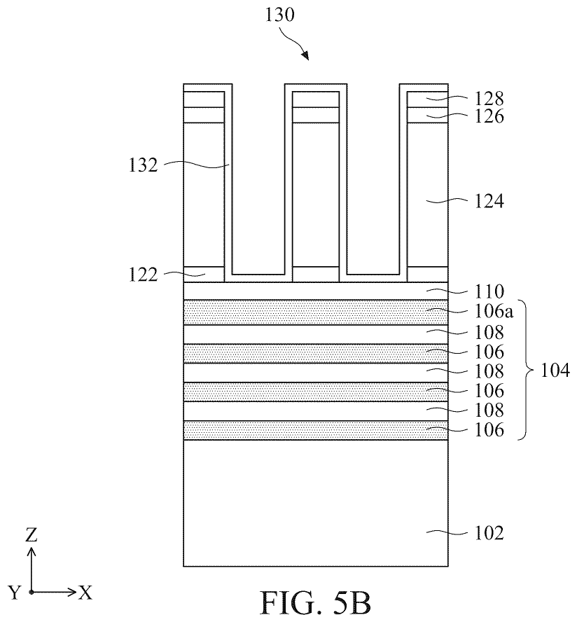

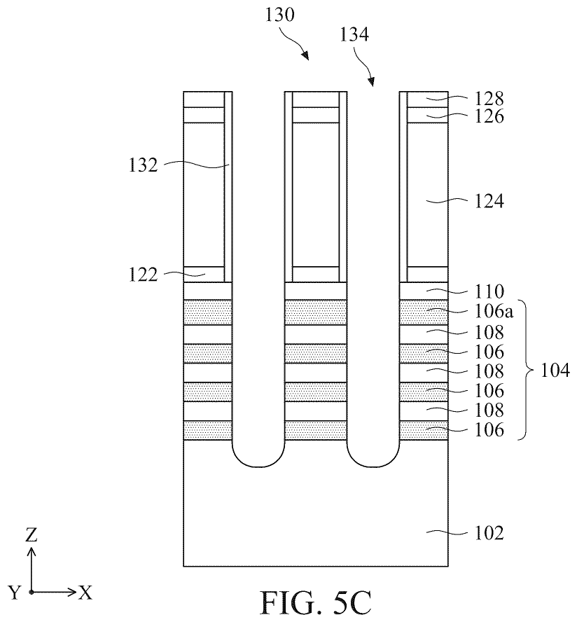

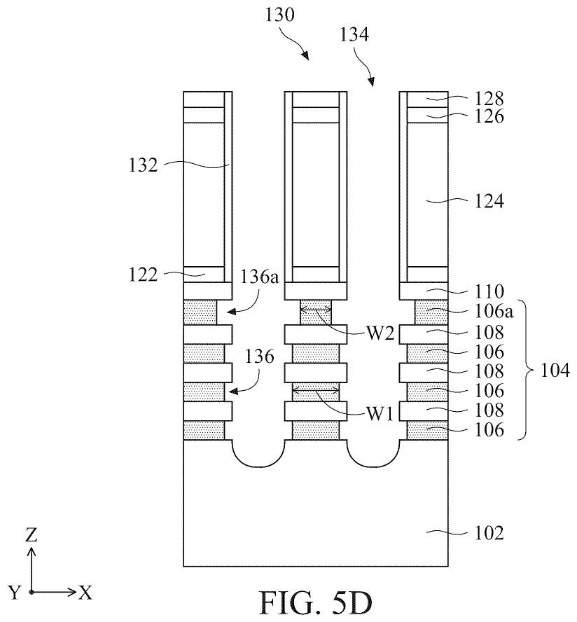

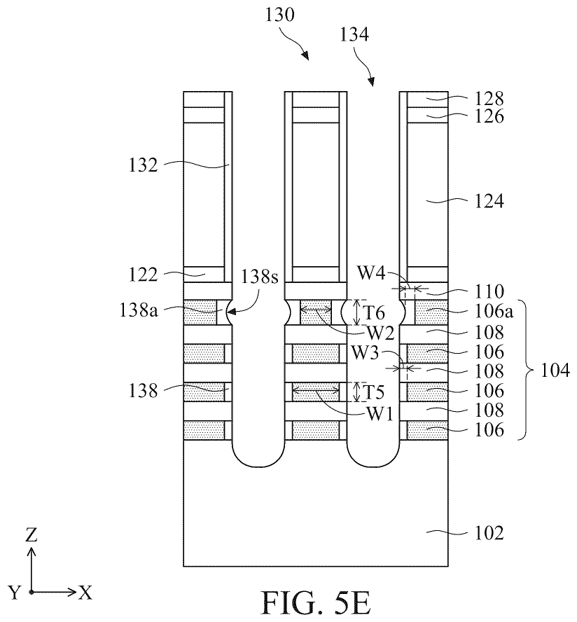

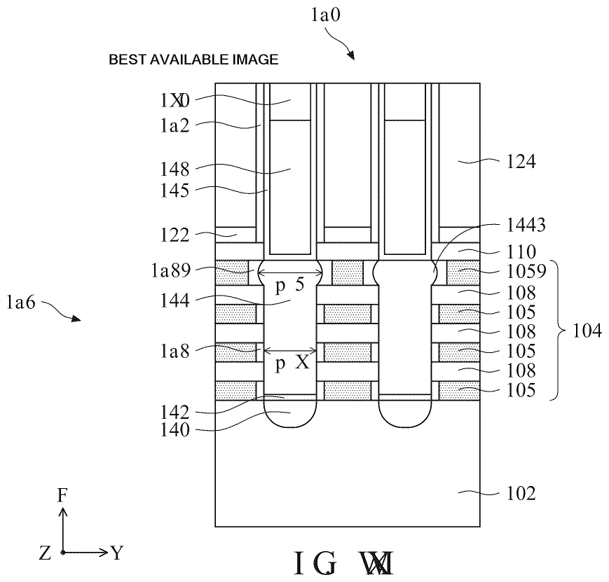

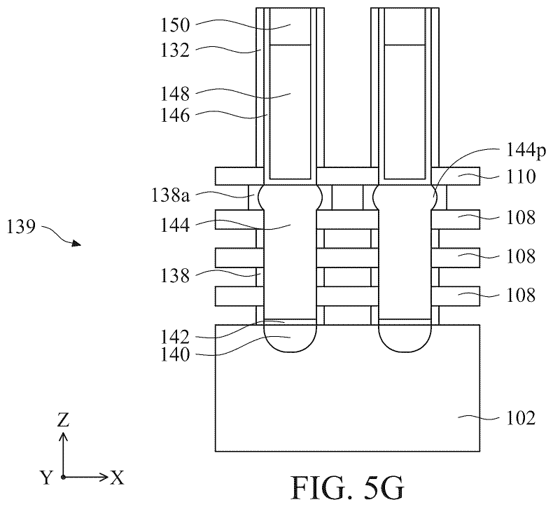

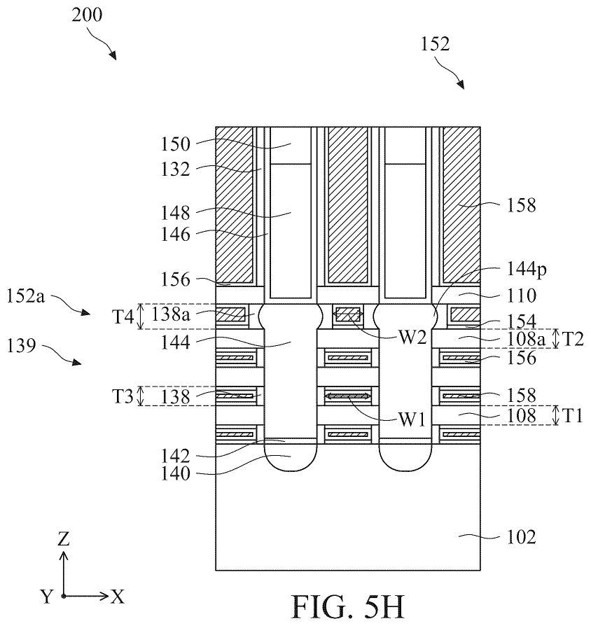

FIGS. 5A to 5H are cross-sectional views of various stages of manufacturing a semiconductor structure 200 in accordance with some embodiments of the present disclosure. FIG. 5A is subsequent to the step of the process that is illustrated in FIG. 1D, and the same or similar reference numbers are used to depict the same or similar components as those of the semiconductor structure 200, so for the sake of simplicity, those components will not be discussed in detail again. In the following embodiments, the top sacrificial layer 106a is thicker than any of the other sacrificial layers 106.

As illustrated in FIG. 5A, a stack 104, including a plurality of sacrificial layers 106, a top sacrificial layer 106a, and a plurality of channel layers 108, may be formed over a substrate 102. The sacrificial layers 106 may have a thickness T3 in the Z-direction, and the top sacrificial layer 106a may have a thickness T4 in the Z-direction. The thickness T3 of the sacrificial layers 106 may be in a range of about 4 nm to about 5 nm. The thickness T4 of the top sacrificial layer 106a may be in a range of about 4 nm to about 8 nm. The thickness T4 of the top sacrificial layer 106a may be greater than the thickness T3 of the sacrificial layers 106. The thickness T4 of the top sacrificial layer 106a may be about 1 nm to about 4 nm greater than the thickness T3 of the sacrificial layers 106. With this thickness difference, a desired etch rate difference between the sacrificial layers 106 and the top sacrificial layers 106a can be achieved, and a desired width of the top inner spacers can be formed subsequently.

Then, as illustrated in FIG. 5B, similar to those discussed with reference to FIG. 2B, a spacer layer 132 may be conformally formed over the hard mask layer 110 and the dummy gate structure 130.

Next, as illustrated in FIG. 5C, similar to those discussed with reference to FIG. 2C, the spacer layer 132 may be etched by an etching process to form a pair of spacer layers 132 on opposite sidewalls of the dummy gate structure 130. Then, the sacrificial layers 106, the top sacrificial layer 106a, and the channel layers 108 may be partially removed in the etching process using the spacer layers 132 as the mask to form a source/drain trench 134.

Next, as illustrated in FIG. 5D, similar to those discussed with reference to FIG. 2D, the sacrificial layers 106 and the top sacrificial layer 106a may be laterally etched from the source/drain trench 134 to form recesses 136 and top recesses 136a, respectively. The channel layers 108 may be not significantly etched. The outer portions of the sacrificial layers 106 and the top sacrificial layer 106a may be removed, and the inner portions of the sacrificial layers 106 and the top sacrificial layer 106a under the dummy gate structure 130 may remain.

The lateral etching of the sacrificial layers 106 and the top sacrificial layer 106a may be a selective dry etching process, a selective wet etching process, or a combination thereof. Since the exposed area of the top sacrificial layer 106a is greater than the exposed area of any of the other sacrificial layers 106, the lateral etching may etch the top sacrificial layer 106a at a higher rate than it etches the other sacrificial layers 106. The amount of the top sacrificial layer 106a that is removed may be greater than the amount of any of the other sacrificial layers 106 that is removed. Therefore, the top recesses 136a may be enlarged with larger widths than the recesses 136 in the X-direction.

The sacrificial layers 106 below the top sacrificial layer 106a may have approximately the same width, such as the width W1. The etched top sacrificial layer 106a may have a width W2, which is less than the width W1 of the etched sacrificial layers 106. In some embodiments, the width W2 of the top sacrificial layer 106a is about 0.3 nm to about 3 nm less than the width W1 of the sacrificial layers 106.

Then, as illustrated in FIG. 5E, similar to those discussed with reference to FIG. 2E, inner spacers 138 may be formed in the recesses 136, and top inner spacers 138a may be formed in the top recesses 136a. Since the top recesses 136a are recessed deeper than the recesses 136, the top inner spacers 138a may have a larger width than the inner spacers 138, thereby providing a longer distance between subsequently formed source/drain structure and gate structure. As a result, the effective capacitance (Ceff) gain can be achieved.

The distance between the inner sidewalls of adjacent inner spacers 138 may be substantially equal to the width W1 of the sacrificial layers 106. The distance between the inner sidewalls of adjacent top inner spacers 138a may be substantially equal to the width W2 of the top sacrificial layer 106a. The distance between the inner sidewalls of adjacent inner spacers 138 may be greater than the distance between the inner sidewalls of adjacent top inner spacers 138a.

In particular, the top inner spacers 138a may have a narrowest width W4 at the middle portion of the top inner spacers 138a. The inner spacers 138 may have a width W3, which is less than the width W4 of the top inner spacers 138a. In some embodiments, the width W4 of the top inner spacers 138a is about 0.3 nm to about 3 nm greater than the width W3 of the inner spacers 138. If the width difference is too large, the space for subsequently formed gate structure would be too small, resulting in increasing difficulty of gate control. If the width difference is too small, there would be not enough distance between subsequently formed source/drain structure and gate structure, leading to the effective capacitance (Ceff) penalty.

The inner spacers 138 below the top inner spacers 138a may have approximately the same thickness, such as thickness T5, in the Z-direction. The top inner spacers 138a may have a thickness T6 in the Z-direction, and the thickness T6 may be greater than the thickness T5 of the inner spacers 138. In some embodiments, the thickness T6 of the top inner spacers 138a is about 0.3 nm to about 2 nm less than the thickness T5 of the inner spacers 138.

Then, as illustrated in FIG. 5F, similar to those discussed with reference to FIG. 2F, a source/drain structure 139 may be formed in the source/drain trench 134. The source/drain structure 139 may include a first epitaxial layer 140, a bottom isolation layer 142 over the epitaxial layer 140, and a second epitaxial layer 144 over the bottom isolation layer 142.

The source/drain structure 139 may have a width W5 at the middle and a width W6 at the top in the X-direction. In particular, the source/drain structure 139 may have the width W5 between the inner spacers 138 or between the channel layers 108 and may have the width W6 between the top inner spacers 138a in the X-direction. The width W6 may be greater than the width W5.

The second epitaxial layer 144 of the source/drain structure 139 may have a protrusion 144p adjoining the top inner spacers 138a. The sidewall of the protrusion 144p of the second epitaxial layer 144 may have a shape corresponding to that of the sidewall of the top inner spacers 138a. The sidewall of the protrusion 144p of the second epitaxial layer 144 may be convex.

Then, an etch stop layer 146 may be conformally formed over the source/drain structure 139 and may be formed over the sidewalls of the hard mask layer 110 and the sidewalls of the spacer layers 132. An ILD structure 148 may be formed over the etch stop layer 146. Then, a planarization process may be performed on the ILD structure 148 until the top surface of the dummy gate structure 130 is exposed. Next, the ILD structure 148 may be recessed and a protection layer 150 may be deposited over the ILD structure 148.

Next, as illustrated in FIG. 5G, similar to those discussed with reference to FIG. 2G, the dummy gate structure 130, the sacrificial layers 106, and the top sacrificial layer 106a may be removed, and the channel layers 108 may be released.

Then, as illustrated in FIG. 5H, similar to those discussed with reference to FIG. 2H, a gate structure 152 may be formed in such a way that it is wrapped around the channel layers 108 and the hard mask layer 110. The portion of the gate structure 152 between the top layer of the channel layers 108 and the hard mask layer 110 may be referred to as an upper gate structure 152a. The gate structure 152 may include an interfacial layer 154, a high-k dielectric layer 156, and a gate electrode layer 158. The channel layers 108 may be surrounded and in contact with the interfacial layer 154. The interfacial layer 154 may be surrounded by the high-k dielectric layer 156. The hard mask layer 110 may be surrounded by the high-k dielectric layer 156. The high-k dielectric layer 156 may be surrounded by the gate electrode layer 158. The gate electrode layer 158 may include one or more work function layers and a metal fill layer.

The gate structure 152 between the channel layers 108 may have the width W1 in the X-direction. The upper gate structure 152a between the top layer of the channel layers 108 and the hard mask layer 110 may have the width W2 in the X-direction. The width W2 of the upper gate structure 152a may be less than the W1 of the gate structure 152. In some embodiments, the width W2 of the upper gate structure 152a is about 0.3 nm to about 3 nm less than the width W1 of the gate structure 152. If the width difference is too large, it would be difficult for gate control. If the width difference is too small, there would be not enough distance between the source/drain epitaxial structure 139 and the upper gate structure 152a, leading to the effective capacitance (Ceff) penalty.

The gate structure 152 between the channel layers 108 may have the thickness T3 in the Z-direction, and the upper gate structure 152a between the top layer of the channel layers 108 and the hard mask layer 110 may have the thickness T4 in the Z-direction. The thickness T3 of the gate structure 152 may be in a range of about 4 nm to about 5 nm. The thickness T4 of the upper gate structure 152a may be in a range of about 4 nm to about 8 nm. The thickness T4 of the upper gate structure 152a may be greater than the thickness T3 of the gate structure 152. The thickness T4 of the upper gate structure 152a may be about 1 nm to about 4 nm greater than the thickness T3 of the gate structure 152.

Then, a planarization process may be performed until the protection layer 150 is exposed. The semiconductor structure 200 may be formed.

The channel layers 108 between the gate structure 152 may have a thickness T1 in the Z-direction, and the top layer of the channel layers 108 (which may be referred to as a top channel layer 108a) adjacent to the upper gate structure 152a may have a thickness T2 in the Z-direction. As illustrated in FIG. 5H, the thickness T1 of the channel layers 108 may be substantially equal to the thickness T2 of the top channel layer 108a.

In some other embodiments, the thickness T2 of the top channel layer 108a is thinner than the thickness T1 of the channel layers 108. The thickness T2 of the top channel layer 108a may be about 0.1 nm to about 1.5 nm thinner than the thickness T1 of the channel layers 108. With this thickness difference, short channel effect (SCE) degradation induced by the upper gate structure 152a being narrower than the gate structure 152 can be recovered.

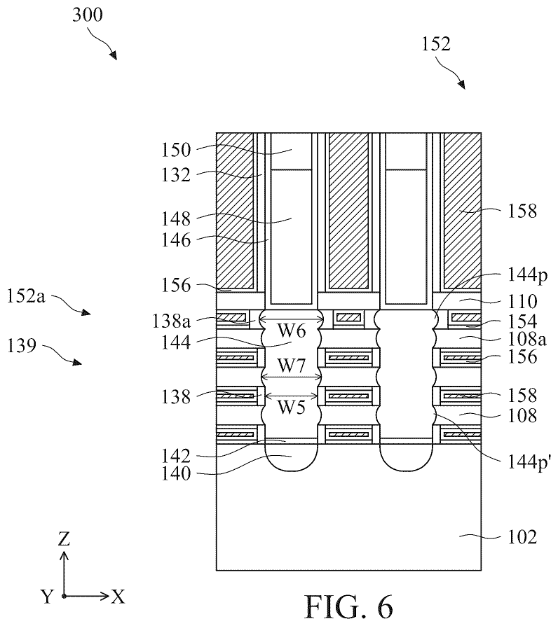

FIG. 6 illustrates a cross-sectional view of a semiconductor structure 300 in accordance with some embodiments of the present disclosure. It should be noted that the semiconductor structure 300 may include the same or similar components as those of the semiconductor structure 100, which is illustrated in FIG. 2H, and for the sake of simplicity, those components will not be discussed in detail again. In the following embodiments, the channel layers 108 are partially removed.

As illustrated in FIG. 6, the channel layers 108 are selectively recessed by using a trimming process, in accordance with some embodiments. The channel layers 108 may be recessed after forming the inner spacers 138 and the top inner spacers 138a and before forming the source/drain structure 139. The trimming process may be performed on the channel layers 108 using an etchant that is selective to the material of the channel layers 108 as compared to with respect to the material of the inner spacers 138 and the top inner spacers 138a. As a result, the sidewalls of the channel layers 108 may be dishing or concave.

After forming the source/drain structure 139, the source/drain structure 139 may have a width W5 between the inner spacers 138, a width W6 between the top inner spacers 138a, and a width W7 between the channel layers 108 in the X-direction. The width W6 may be greater than, substantially equal to, or less than the width W7. The width W7 may be greater than the width W5. The source/drain structure 139 may have a plurality of protrusions 144p′ adjoining the channel layers 108. The sidewall of the protrusions 144p′ of the second epitaxial layer 144 may each have a shape corresponding to that of the sidewall of the channel layers 108. The sidewall of the protrusion 144p′ of the second epitaxial layer 144 may be convex.

Each of the protrusion 144p′ of the second epitaxial layer 144 may be surrounded by one of the channel layers 108. The protrusion 144p′ of the second epitaxial layer 144 may protrude laterally beyond the sidewall of the hard mask layer 110 when viewed from above, or from a direction that is parallel to the sidewall of the hard mask layer 110. The protrusion 144p′ of the second epitaxial layer 144 may protrude laterally beyond the sidewall of the channel layers 108 when viewed from above, or from a direction that is parallel to the sidewall of the channel layers 108. The protrusion 144p′ of the second epitaxial layer 144 may protrude laterally beyond the sidewall of the inner spacers 138 when viewed from above, or from a direction that is parallel to the sidewall of the inner spacers 138.

Of the protrusions 144p′, the top one may adjoin the protrusion 144p. The protrusion 144p may protrude laterally beyond the protrusions 144p′ when viewed from above, or from a direction that is parallel to the sidewall of the inner spacers 138. In particular, the sidewall of the channel layers 108 may be between the sidewall of the top inner spacers 138a and the sidewall of the inner spacers 138 when viewed from above. The sidewalls of the adjacent protrusions 144p′ may be connected with a substantially straight sidewall of the second epitaxial layer 144.

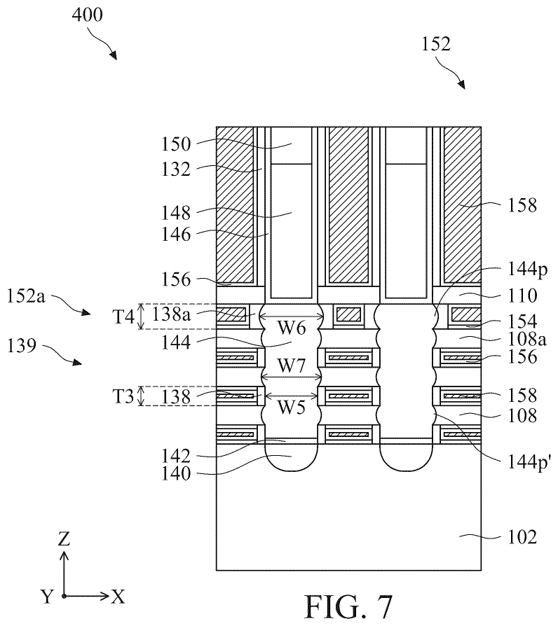

FIG. 7 illustrates a cross-sectional view of a semiconductor structure 400 in accordance with some embodiments of the present disclosure. It should be noted that the semiconductor structure 400 may include the same or similar components as those of the semiconductor structure 200, which is illustrated in FIG. 5H, and for the sake of simplicity, those components will not be discussed in detail again. In the following embodiments, the channel layers 108 are partially removed, similar to those discussed with reference to FIG. 6.

As illustrated in FIG. 7, the thickness T4 of the upper gate structure 152a between the top layer of the channel layers 108 and the hard mask layer 110 may be greater than the thickness T3 of the gate structure 152 between the channel layers 108. The sidewalls of the channel layers 108 may be dishing or concave due to selectively recessing the channel layers 108 by a trimming process. The source/drain structure 139 may have a width W5 between the inner spacers 138, a width W6 between the top inner spacers 138a, and a width W7 between the channel layers 108 in the X-direction. The width W6 may be greater than, substantially equal to, or less than the width W7. The width W7 may be greater than the width W5. The source/drain structure 139 may have a plurality of protrusions 144p′ adjoining the channel layers 108. The sidewalls of the protrusions 144p′ of the second epitaxial layer 144 may each have a shape corresponding to that of the sidewall of the channel layers 108. The sidewalls of the protrusion 144p′ of the second epitaxial layer 144 may be convex.

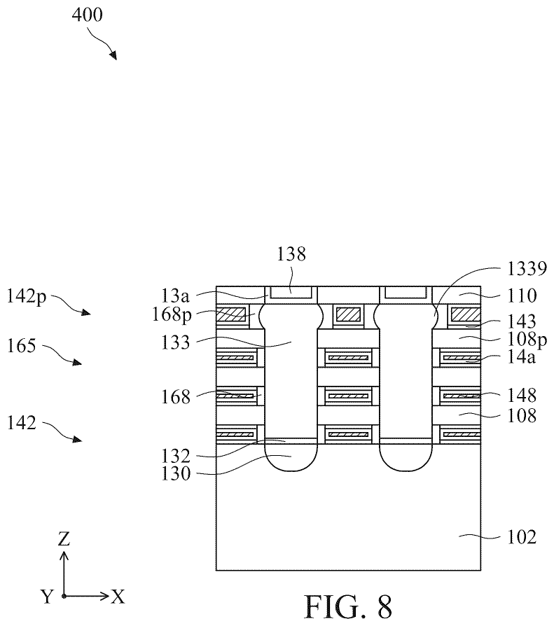

FIG. 8 illustrates a cross-sectional view of a semiconductor structure 500 in accordance with some embodiments of the present disclosure. It should be noted that the semiconductor structure 800 may include the same or similar components as those of the semiconductor structure 100, which is illustrated in FIG. 2H, and for the sake of simplicity, those components will not be discussed in detail again. In the following embodiments, portions of the gate structure 152 over the hard mask layer 110 are removed.

Since the hard mask layer 110 is used, the top channel layer 108a may be controlled by the gate structure 152 between the top channel layer 108a and the hard mask layer 110, instead of the gate structure 152 above the hard mask layer 110. Therefore, the gate structure 152 above the top channel layer 108a can be shorten to reduce some resistance-capacitance (RC) issue. The gate structure 152 above the top channel layer 108a would be shorter than a GAA structure without the hard mask layer 110 since the top gate structure 152 is used to control the top channel layer in the GAA structure. Accordingly, the size of the resulting transistor may be reduced.

As illustrated in FIG. 8, after performing the processes shown in FIGS. 2A to 2G described above, the gate structure 152 is formed around the channel layers 108 and the hard mask layer 110, and a planarization process is performed until exposing the top surface of the hard mask layer 110 in accordance with some embodiments. By performing the planarization process, the height of portions of the gate structure 152 is reduced and the size of the resulting transistor is therefore reduced. The planarization process may include a grinding process, a chemical mechanical polishing (CMP) process, another suitable process, or a combination thereof. In some embodiments, the height of portions of the gate structure 152 over the hard mask layer 110 is reduced to 0. That is, a topmost surface of the gate structure 152 is lower than a top surface of the hard mask layer 110 in accordance with some embodiments. In some embodiments, the topmost surface of the gate structure 152 is lower than a top surface of the ILD structure 148. In some embodiments, the topmost surface of the gate structure 152 is in contact with a bottom surface of the hard mask layer 110. As a result, the top surface of the hard mask layer 110 may be exposed. The RC issue can be reduced.

As described previously, the top sacrificial layer 106a is recessed deeper than the other sacrificial layers 106 are in the same process, so that the subsequently formed top inner spacers 138a have a larger width than the inner spacers 138. Accordingly, the distance between the source/drain structure 139 and the gate structure 152 can be increased, thereby reducing the effective capacitance (Ceff). In some embodiments as illustrated in FIG. 2H, the germanium concentration of the top sacrificial layer 106a is higher than that of the sacrificial layers 106. In some embodiments as illustrated in FIG. 5H, the top sacrificial layer 106a is thicker than one of the sacrificial layers 106. In some embodiments as illustrated in FIGS. 6 and 7, the channel layers 108 are recessed after forming the inner spacers 138 and the top inner spacers 138a and before forming the source/drain structure 139. In some embodiments as illustrated in FIG. 8, the top surface of the hard mask layer 110 is exposed.

Embodiments of a semiconductor structure and a method for forming the semiconductor structure are provided. The method of forming the semiconductor structure may include increasing the germanium concentration or the thickness of the top sacrificial layer, so that a greater amount of the top layer can be removed than any of the other layers in the same process. Therefore, the top inner spacer separating the source/drain structure and the gate structure can be widened, and thus the effective capacitance (Ceff) can be reduced.

In some embodiments, a method for forming a semiconductor structure is provided. The method for forming a semiconductor structure includes alternately forming a plurality of channel layers and a plurality of sacrificial layers over a substrate. The method for forming a semiconductor structure also includes forming a top sacrificial layer over the channel layers and the sacrificial layers. The method for forming a semiconductor structure also includes forming a source/drain trench through the top sacrificial layer, the channel layers, and the sacrificial layers. The method for forming a semiconductor structure also includes recessing the top sacrificial layer and the sacrificial layers through the source/drain trench so that a first width of the top sacrificial layer is less than a second width of the sacrificial layers. The method for forming a semiconductor structure also includes forming a plurality of inner spacers on sidewalls of the top sacrificial layer and sidewalls of the sacrificial layers. The method for forming a semiconductor structure also includes replacing the top sacrificial layer and the sacrificial layers with a gate structure.

In some embodiments, a method for forming a semiconductor structure is provided. The method for forming a semiconductor structure includes forming a stack over a substrate. The stack includes a top sacrificial layer and a plurality of sacrificial layers interleaved by a plurality of channel layers. The method for forming a semiconductor structure also includes etching the stack to form a source/drain trench. The method for forming a semiconductor structure also includes partially removing the top sacrificial layer and the sacrificial layers. The method for forming a semiconductor structure also includes forming a top inner spacer on a sidewall of the top sacrificial layer and a plurality of inner spacers on sidewalls of the sacrificial layers. A width of the top inner spacer is greater than a width of the inner spacers. The method for forming a semiconductor structure also includes forming a source/drain structure in the source/drain trench and having a first curved sidewall adjoining the top inner spacer. The method for forming a semiconductor structure also includes replacing the top sacrificial layer and the sacrificial layers with a gate structure.

In some embodiments, a semiconductor structure is provided. The semiconductor structure includes nanostructures formed over a substrate. The semiconductor structure also includes a source/drain structure attached to the nanostructures. The semiconductor structure also includes a gate structure wrapped around the nanostructures. The semiconductor structure also includes a hard mask layer disposed over the nanostructures. The semiconductor structure also includes inner spacers disposed between the source/drain structure and the gate structure. The semiconductor structure also includes a top inner spacer disposed between a top portion of the source/drain structure and the gate structure. The gate structure has a first portion adjacent to the top inner spacer and a second portion adjacent to the inner spacers, and a width of the first portion is less than a width of the second portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
alternately forming a plurality of channel layers and a plurality of sacrificial layers over a substrate;
forming a top sacrificial layer over the channel layers and the sacrificial layers;
forming a source/drain trench through the top sacrificial layer, the channel layers, and the sacrificial layers;
recessing the top sacrificial layer and the sacrificial layers through the source/drain trench so that a first width of the top sacrificial layer is less than a second width of the sacrificial layers;
forming a plurality of inner spacers on sidewalls of the top sacrificial layer and sidewalls of the sacrificial layers; and
replacing the top sacrificial layer and the sacrificial layers with a gate structure.

2. The method for forming the semiconductor structure as claimed in claim 1, wherein a first germanium concentration of the top sacrificial layer is greater than a second germanium concentration of the sacrificial layers.

3. The method for forming the semiconductor structure as claimed in claim 2, wherein the first germanium concentration of the top sacrificial layer is about 10% to about 35% greater than the second germanium concentration of the sacrificial layers.

4. The method for forming the semiconductor structure as claimed in claim 1, wherein a first thickness of the top sacrificial layer is greater than a second thickness of the sacrificial layers.

5. The method for forming the semiconductor structure as claimed in claim 4, wherein the first thickness of the top sacrificial layer is about 1 nm to about 4 nm greater than the second thickness of the sacrificial layers.

6. The method for forming the semiconductor structure as claimed in claim 1, further comprising recessing the channel layers after forming the inner spacers so that a sidewall of the channel layers is between a sidewall of a top inner spacer and a sidewall of a bottom inner spacer when viewed from above.

7. The method for forming the semiconductor structure as claimed in claim 1, further comprising:
forming a source/drain structure in the source/drain trench,
wherein the source/drain structure has a protrusion extending toward the top sacrificial layer.

8. A method for forming a semiconductor structure, comprising:
forming a stack over a substrate, wherein the stack comprises a top sacrificial layer and a plurality of sacrificial layers interleaved by a plurality of channel layers;
etching the stack to form a source/drain trench;
partially removing the top sacrificial layer and the sacrificial layers;
forming a top inner spacer on a sidewall of the top sacrificial layer and a plurality of inner spacers on sidewalls of the sacrificial layers, wherein a width of the top inner spacer is greater than a width of the inner spacers;
forming a source/drain structure in the source/drain trench and having a first curved sidewall adjoining the top inner spacer; and
replacing the top sacrificial layer and the sacrificial layers with a gate structure.

9. The method for forming the semiconductor structure as claimed in claim 8, further comprising:
forming a hard mask layer over the stack;
patterning the stack with the hard mask layer; and
partially removing the hard mask layer and leaving a portion of the hard mask layer in contact with the top sacrificial layer.

10. The method for forming the semiconductor structure as claimed in claim 8, wherein an amount of the top sacrificial layer removed is greater than an amount of one of the sacrificial layers removed during partially removing the top sacrificial layer and the sacrificial layers.

11. The method for forming the semiconductor structure as claimed in claim 8, further comprising:
partially removing the channel layers before forming the source/drain structure,
wherein the source/drain structure has second curved sidewalls adjoining the channel layers, and a width at the first curved sidewalls is greater than a width at the second curved sidewall.

12. The method for forming the semiconductor structure as claimed in claim 8, wherein a thickness of a top channel layer is thinner than a thickness of a bottom channel layer.

13. The method for forming the semiconductor structure as claimed in claim 8, wherein a thickness of the top inner spacer is greater than a thickness of the inner spacers.

14. A semiconductor structure, comprising:
nanostructures formed over a substrate;
a source/drain structure attached to the nanostructures;
a gate structure wrapped around the nanostructures;
a hard mask layer disposed over the nanostructures;
inner spacers disposed between the source/drain structure and the gate structure; and
a top inner spacer disposed between a top portion of the source/drain structure and the gate structure,
wherein the gate structure has a first portion adjacent to the top inner spacer and a second portion adjacent to the inner spacers, and a width of the first portion is less than a width of the second portion.

15. The semiconductor structure as claimed in claim 14, wherein a thickness of the top inner spacer is about 0.3 nm to about 3 nm greater than a thickness of the inner spacers.

16. The semiconductor structure as claimed in claim 14, wherein a thickness of the first portion is about 0.3 nm to about 3 nm greater than a thickness of the second portion.

17. The semiconductor structure as claimed in claim 14, wherein a top one of the nanostructures is about 0.1 nm to about 5 nm thinner than the other nanostructures.

18. The semiconductor structure as claimed in claim 14, wherein the top inner spacer has a first curved sidewall below the hard mask layer.

19. The semiconductor structure as claimed in claim 18, wherein the nanostructures have a second curved sidewall, and the second curved sidewall is between the first curved sidewall and a sidewall of the inner spacers when viewed from above.

20. The semiconductor structure as claimed in claim 18, wherein the first curved sidewall is in contact with a sidewall of the hard mask layer.
